(19) United States
(12) Patent Application Publication
(10) Pub. No.: US 2007/0015010 A1
(43) Pub. Date: Jan. 18, 2007

(54) Magnetic disk, manufacturing method therefor and magnetic recording device

(75) Inventors: Shigeru Horigome, Higashine (JP); Takashi Arai, Higashine (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: FUJITSU LIMITED, Kawasaki (JP)

(21) Appl. No.: 11/481,249

(22) Filed: Jul. 6, 2006

Related U.S. Application Data
(63) Continuation-in-part of application No. 11/126,337, filed on May 11, 2005.

(30) Foreign Application Priority Data
Jan. 10, 2006 (JP) 2006-002970
Jan. 7, 2005 (JP) 2005-002971

(51) Int. Cl. G11B 5/64; C23C 14/00

(52) U.S. Cl. 428/826; 204/192.2

(57) ABSTRACT

In a step of forming the under layer, the under layer is formed while an insulating substrate is supported by support members made of a conductive material. In a step of forming a recording layer, the insulating substrate remains supported. A movable electrode is urged into contact with an end face of the insulating substrate. The recording layer is formed by a sputtering process while a negative bias voltage is applied. Since the under layer is formed on the end face of the substrate, the electric conduction between the movable electrode and the under layer is good. Moreover, the under layer formed on the surface of the substrate is bridged to a part of a contact section of the support springs. Therefore, the support springs and the under layer is electrically connected. A bias voltage is applied to the under layer through the movable electrode and the support springs.

### BACKGROUND OF THE INVENTION

1. Field of the Invention

The present invention relates to a magnetic disk, a manufacturing method therefor and magnetic recording device, and particularly relates to a magnetic disk manufacturing method that forms a recording layer and the like by applying a bias voltage to a substrate.

2. Description of the Related Art

In recent years, as magnetic recording devices have become used for recording high-resolution digital static images and dynamic images, a demand for larger capacity and higher recording density is growing. Being small and light as well as having a high access performance, magnetic recording devices, especially magnetic disk devices, are more often used in audio/visual recording equipment for home-use and mobile terminals.

Due to such circumstances, developments for reducing thickness and increasing coercivity of magnetic layers of magnetic disks used in the magnetic disk devices are in progress in order to boost recording density. However, if the recording density is increased, demagnetic fields that demagnetize the magnetic layers are intensified. Therefore, it is necessary to have high coercivity for suppressing the demagnetic fields. A reduction of thickness of the magnetic layers is also necessary because thicker magnetic layers generate greater diamagnetic fields.

In the case where magnetic disk devices are used in mobile terminals, the magnetic disk devices are often subjected to vibration and shocks. Substrates of magnetic disks have commonly been formed of aluminum alloys. However, if a shock occurs during recording/reproducing operations and a magnetic head hits a surface of the magnetic disk, the aluminum alloy substrate is easily dented or damaged. For this reason, aluminum alloy substrates are being replaced by glass substrates having higher elasticity.

Layers constituting magnetic disks are formed by a sputtering process or a Plasma CVD (Chemical Vapor Deposition) process. When a magnetic layer is formed by the sputtering process, a substrate holder is used for supporting a substrate upright to allow formation of the layer on both sides of the substrate (see, for example, Reference 1: Japanese Patent Laid-Open Publication No. 7-243037 and Reference 2: Japanese Patent Laid-Open Publication No. 9-7174). The substrate is held by claw-like support members of the substrate holder at the end face of the outer edge of the substrate. In this state, Ar ions or the like strike a target in a vacuum processing chamber. Then, sputtered metal particles are deposited on an under layer formed on the non-magnetic substrate. Since the metal particles are positively charged in this process, a negative bias is applied to the non-magnetic substrate so as to accelerate the metal particles. It is known that the coercivity of the magnetic layer can be improved by such acceleration of the metal particles.

In reference to Reference 1, the bias is applied through the claw-like support members of the substrate holder. To ensure contact between the support members and the under layer formed on the insulating substrate, there is provided a changing mechanism that rotates the substrate so as to change positions on the end face contacted by the support members before the magnetic layer is formed.

Reference 2 discloses a substrate holder 100 as shown in FIG. 1, wherein a substrate 101 is held by support members 103, and a bias is applied through a bias application terminal 104 in contact with an end face on the lower side of the substrate 101.

According to Reference 1, because the rotation of the substrate by the changing mechanism is performed in a vacuum processing chamber, it is necessary to have an additional vacuum processing chamber in which the changing mechanism is installed. The cost of the vacuum processing chamber, which is several hundred thousand dollars, affects manufacturing costs. If there is no space available for the vacuum processing chamber for the changing mechanism and therefore the changing mechanism is installed in an existing vacuum processing chamber supposed to be used for forming a layer, the number of layers to be formed should be reduced. Consequently, design of the magnetic disks is restricted. In addition, since operations for removing, rotating and holding the substrate are required, the substrate might be incorrectly held or unexpectedly dropped.

According to Reference 2, the bias application terminal 104 is moved upward by a cross bar 105 to bring a contact section 104a into contact with the lower side of the substrate 101 as shown in FIG. 1, and the bias is applied in this state. Since the bias voltage is applied only through the contact section 104a, the bias voltage might be delivered unevenly within a magnetic disk having a thin under layer. This causes nonuniform distribution of a coercive force within the magnetic disk.

### SUMMARY OF THE INVENTION

A general object of the present invention is to provide a magnetic disk, a manufacturing method therefor and a magnetic recording device that solve at least one problem described above. A specific object of the present invention is to provide a high recording density magnetic disk to which a bias voltage is applied without repositioning a substrate and on which a coercive force is uniformly distributed, a manufacturing method therefor and magnetic recording device.

According to an aspect of the present invention, there is provided a magnetic disk manufacturing method which comprises a first step of forming a conductive layer on a surface of an insulating substrate supported by plural substrate support members that are made of a conductive material and are connected to a conductive substrate holder, and a second step of forming a recording layer on the conductive layer by a sputtering process while applying a negative bias voltage to the conductive layer. In the second step, a movable electrode is brought into contact with the conductive layer on an end face of the insulating substrate that is kept supported, and the recording layer is formed while applying the bias voltage to the conductive layer through the movable electrode and the substrate support members.

In this magnetic disk manufacturing method, a conductive layer is formed on an insulating substrate supported by plural substrate support members made of a conductive material in the first step. While the insulating substrate is kept supported as it is, a movable electrode is brought into contact with an end face of the insulating substrate in the second step. A recording layer is formed by a sputtering process while applying a negative bias voltage to the conductive layer. The conductive layer is formed on the end face of the insulating substrate, so that the electric conduction between the movable electrode and the conductive layer is good. Moreover, the conductive layer is formed to bridge a part of a contact section between the insulating substrate and the support members. Therefore, the support members and the conductive layer is electrically connected. Therefore, the bias voltage is uniformly supplied to the conductive layer through the movable electrode and the plural support members. With the bias voltage supplied in this manner, the recording layer can be formed to have an uniformly distributed coercive force. As a result, the recording density of a magnetic disk can be increased. In addition, since the bias voltage is supplied from plural points, generation of abnormal electrical discharge and defects caused by the generation of the abnormal electrical discharge are minimized. This contributes to improve the yield.

Unlike the related art described above, there is no need to change the substrate holders for rotating the substrate before forming the recording layer. Accordingly, the cost for a facility for these operations can be saved. Therefore, the manufacturing cost is reduced.

The movable electrode may include an electrode body, a contact terminal provided on a front end of the electrode body, and an electrode spring. Also, the contact terminal may be kept out of contact with the end face with a biasing force of the electrode spring in the first step, and the movable electrode may be pressed in a direction opposite to a direction of the biasing force of the electrode spring such that the contact terminal is kept in contact with the conductive layer on the end face in the second step. With this configuration, the coercive force of the recording layer is further uniformly distributed. This simple configuration is capable of keeping the electrode out of contact with the end face of the substrate with a biasing force of the electrode spring of the movable electrode while the bias voltage is not supplied.

The movable electrode may be arranged at the upper side of the insulating substrate, and the movable electrode may be pressed downward by a pressing part provided in a vacuum processing chamber so as to bring the contact terminal into contact with the conductive layer on the end face on the upper side of the insulating substrate. The pressing part can be provided on the upper side of the vacuum processing chamber where there are relatively less spatial limitations.

When the movable electrode contacts the end face, the movable electrode may apply a force onto the insulating substrate in a circumferential direction of the insulating substrate so as to move the positions of the end face of substrate contacted by the support springs relative to the support springs. By moving the contact positions, the movable electrode can more securely contact the conductive layer formed on the end face of the substrate.

According to another aspect of the present invention, there is provided a magnetic disk manufactured by the above-described disk manufacturing method, comprising an insulating substrate, a conductive layer formed on the insulating substrate, and a recording layer formed on the conductive layer.

This magnetic disk has a recording layer having an uniformly distributed coercive force and therefore has a high recording density. This contributes to minimize defective magnetic disks, and consequently improves the yield.

According to still another aspect of the present invention, there is provided a magnetic recording device which comprises the above-described magnetic disk and a recording and reproducing part.

Because the magnetic disk has a high recording density and the yield is high, the magnetic recording device having a large capacity can be manufactured at low manufacturing cost.

### BRIEF DESCRIPTION OF THE DRAWINGS

FIG. 1 shows a related-art bias-applying mechanism;

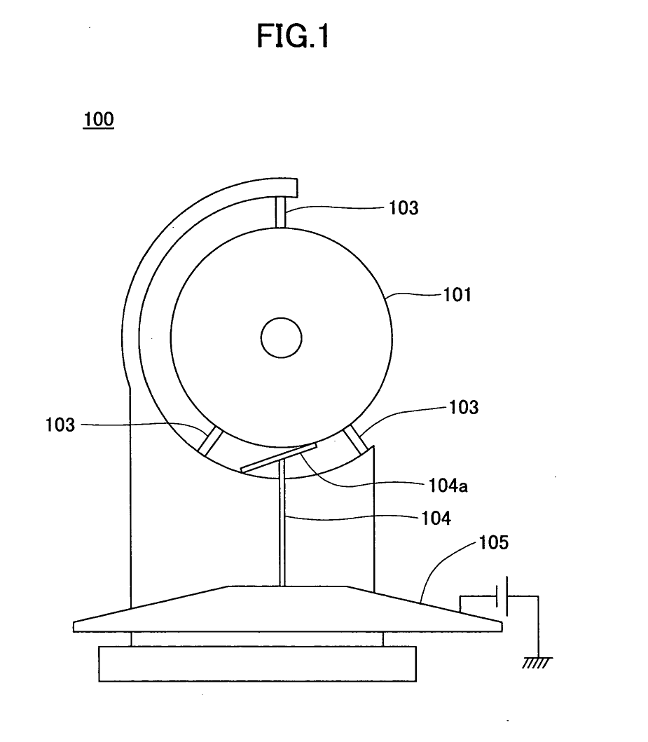

FIG. 2 is a cross-sectional view showing an example of a magnetic disk manufactured by a manufacturing method according to a first embodiment of the present invention;

FIG. 3 is a schematic diagram showing a magnetic disk manufacturing apparatus;

FIG. 4 is a schematic diagram showing a vacuum processing chamber used for a manufacturing method according to the first embodiment;

FIGS. 5A and 5B are front views of a substrate holder according to a first example of the first embodiment;

FIG. 6 is an illustration showing a state of contact between a contact section of a support spring and an under layer;

FIGS. 7A and 7B are front views of a substrate holder according to a second example of the first embodiment;

FIG. 8 is a front view of a substrate holder according to a third example of the first embodiment;

FIGS. 9A and 9B are front views of a substrate holder according to a fourth example of the first embodiment;

FIGS. 10A and 10B are front views of a substrate holder according to a fifth example of the first embodiment;

FIG. 11 is a drawing showing the characteristics of coercive force of the magnetic disk according to working examples of the first embodiment; and

FIG. 12 shows main parts of a magnetic recording device according to a second embodiment of the present invention.

### DETAILED DESCRIPTION OF THE PREFERRED EMBODIMENT

Exemplary embodiments of the present invention are described hereinafter with reference to the accompanying drawings.

### First Embodiment

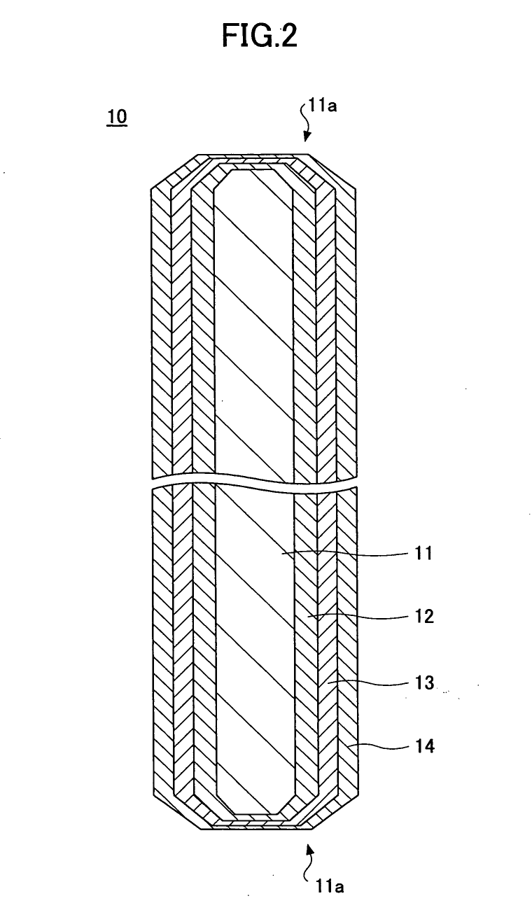

FIG. 2 is a cross-sectional view showing an example of a magnetic disk manufactured by a manufacturing method according to a first embodiment of the present invention.

Referring to FIG. 2, a magnetic disk 10 comprises a substrate 11, an under layer 12 formed on the substrate 11, a recording layer 13 formed on the under layer 12, and a protection film 14 formed on the recording layer 13.

The substrate 11 is formed of a disk-shaped non-magnetic insulating material, including glass substrates, plastic substrates and ceramic substrates. The substrate 11 may have a patterned surface, or a textured surface. The texture includes laser texture, mechanical texture and the like. The substrate 11 may also have mechanical texture having a number of elongated grooves in the circumferential direction.

The under layer 12 is made of non-magnetic Cr or a Cr—X alloy (X=Mo, W, V, B, or any one of alloys of these elements). For example, the under layer 12 may be made of Cr, CrMo, or CrW. With the under layer 12, an easy magnetization direction of the recording layer 13 can be set to a direction parallel to the substrate 11, or, can be set to a so-called in-plane direction. The under layer 12 has electrical conductivity. A bias voltage is applied to the under layer 12 when the recording layer 13 is formed.

The recording layer 13 is made of a ferromagnetic material such as Co, Ni, Fe, Co alloys, Ni alloys, or Fe alloys. Particularly, CoCr, a CoCr alloy, CoCrTa, a CoCrTa alloy, CoCrPt and a CoCrPt alloy are preferable among the Co alloys. In the recording layer 13, two ferromagnetic layers and a non-magnetic interlayer therebetween are stacked, and the magnetisms of the two ferromagnetic layers are antiferromagnetically coupled to each other via the non-magnetic interlayer.

The protection film 14 may be made of, without being limited thereto, amorphous carbon, carbon hydride, or carbon nitride. The protection film 14 is formed by the sputtering process or Plasma CVD process. When the protection film 14 is formed by the Plasma CVD process, a bias voltage is supplied as in a process of formation of the recording layer 13. Supplying a bias voltage helps to improve the quality and the density of the protection film 14.

Although not shown in the drawings, one or more seed layers made of metal materials may be provided between the substrate 11 and the under layer 12. The seed layers have electrical conductivity. Therefore, when the recording layer 13 and the protection film 14 are formed by providing a bias voltage, the bias voltage is applied to the seed layers together with the under layer 12. With reference to FIG. 2, an end face 11a of the outer edge of the substrate 11 is also covered with the under layer 12, the recording layer 13 and the protection film 14 as will be described below in greater detail.

The following describes a magnetic disk manufacturing method according to a first embodiment of the present invention.

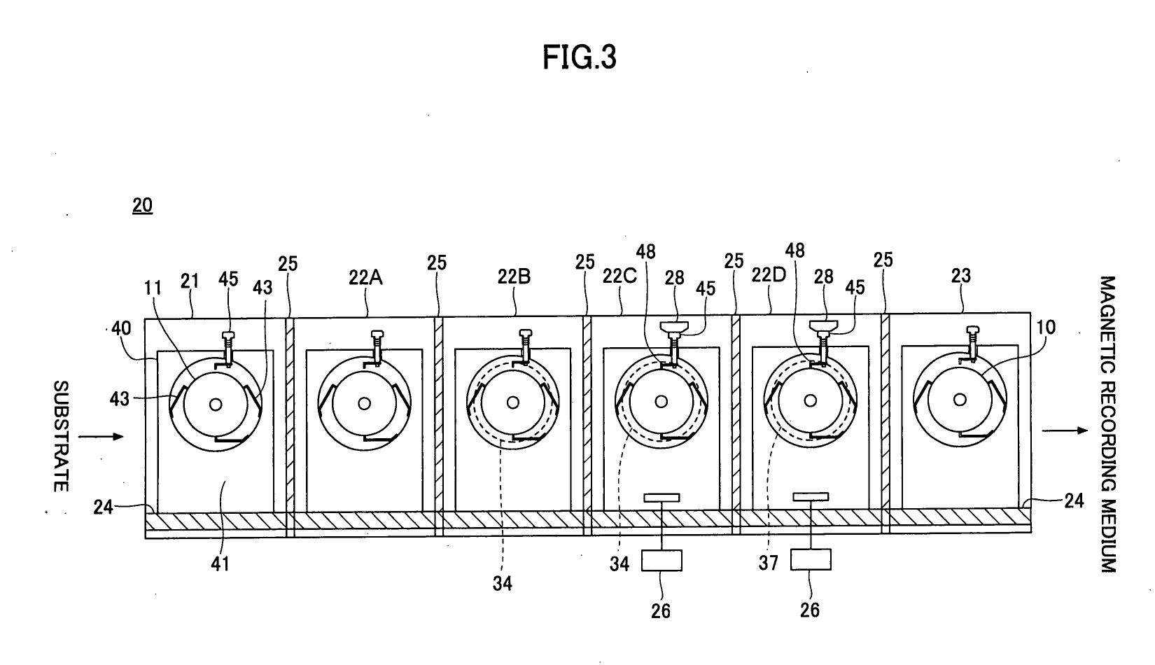

FIG. 3 is a schematic diagram showing a magnetic disk manufacturing apparatus 20. Referring to FIG. 3, the manufacturing apparatus 20 comprises a load lock chamber 21, vacuum processing chambers 22A through 22D, an unload lock chamber 23, and gate valves 25 for isolating the chambers 21 through 23 from each other. The manufacturing apparatus 20 also comprises a substrate holder 40 for supporting the substrate 11, and a transfer mechanism 24 for transferring the substrate holder 40 from the load lock chamber 21 to the unload lock chamber 23 through the vacuum processing chambers 22A through 22D. Although not illustrated in FIG. 3, the manufacturing apparatus 20 further comprises gas supply mechanisms and evacuation mechanisms (both not shown).

First, the substrates 11 loaded in a cartridge or the like are supplied to the manufacturing apparatus 20. A robot (not shown) removes the substrates 11 from the cartridge one by one and places the substrate 11 on the substrate holder 40. The substrate 11 is held by plural support springs 43 (to be discussed below in detail) provided on the inner circumference of an opening of the substrate holder 40. In this embodiment, three support springs 43 are provided. The support springs 43 are arranged such that respective contact points between the support springs 43 and the substrate 11 are 120 degrees apart from each other with respect to the center of the substrate 11. With this arrangement, the substrate 11 can be stably supported. While the three support springs 43 are provided in this embodiment, two or more than three support springs 43 may be provided instead.

Next, the air inside the load lock chamber 21 is evacuated by the evacuation mechanism to create a vacuum atmosphere. When the vacuum atmosphere is created, the gate valve 25 is opened to transfer the substrate holder 40 to the next vacuum processing chamber 22A. While treatments are performed in each of the vacuum processing chambers 22A through 22D, the gate valves 25 are kept closed. However, in the case where the vacuum processing chambers 22A through 22D are set to the same atmosphere, the treatments in the chambers 22A through 22D may be performed with the gate valves 25 open. Operations of the gate valves 25 are not further discussed in the following description.

In the vacuum processing chamber 22A, the substrate 11 is heated. The inside of the vacuum processing chamber 22A is set to an Ar gas atmosphere with pressure of, for example, 0.67 Pa. The substrate 11 is heated to approximately 200° C. by a heater such as a Pyrolytic Boron Nitride heater. This heat treatment of the substrate 11 contributes to the making of a high-quality under layer 12 and recording layer 13 in the process that follows. The heat treatment can also remove water and contamination from the surface of the substrate 11. Then, the substrate holder 40 holding the substrate 11 is transferred to the next vacuum processing chamber 22B.

In the vacuum processing chamber 22B, the under layer 12 is formed on the surface of the substrate 11 by the sputtering process.

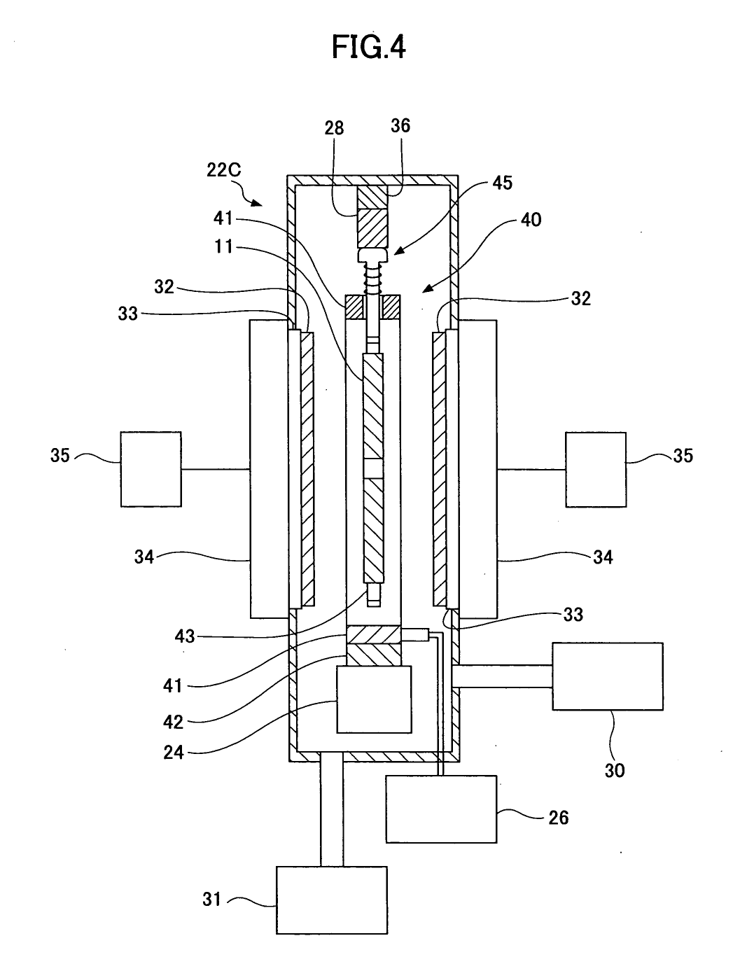

FIG. 4 is a schematic diagram showing the vacuum processing chamber 22C used for a manufacturing the explanation of the method according to the first embodiment. Although the vacuum processing chamber 22C shown in FIG. 4 is used for forming the recording layer 13, the components of the vacuum processing chamber 22B are also shown in FIG. 4, and therefore, the process of forming the under layer 12 is also described with reference to FIG. 4.

Referring then to FIG. 4, the substrate holder 40 fixed to the transfer mechanism 24 is located at the center. A target 32, a target holder 33, a cathode 34, and a sputtering power source 35 connected to the cathode 34 are provided on each side of the substrate holder 40. A gas supply mechanism 30 for supplying Ar gas or the liked and a gas evacuation mechanism 31 for evacuating are installed inside the vacuum processing chamber 22C.

In the vacuum processing chamber 22B, the under layer 12 is formed with use of the target 32 made of Cr or Cr—X alloy materials described above by, for example, DC magnetron sputtering. The vacuum processing chamber 22C is set to, for example, an Ar gas atmosphere with pressure of 0.67 Pa. The thickness of the under layer 12 is set as desired. If the thickness of the under layer 12 is set to around, for example, several nm through about 20 nm, it is preferable to provide a seed layer between the substrate 11 and the under layer 12 for uniformly applying a bias. The seed layer may be an amorphous metal film made of, for example, NiP, and the thickness of the seed layer may be set to around 5 nm through 100 nm. The seed layer may also be made of AlRu having a B2 crystal structure. The under layer 12 or a lamination layer of the seed layer and the under layer 12 serving as a conductive layer can be made thick in this way. Referring back to FIG. 3, the substrate holder 40 holding the substrate 11 is transferred to the next vacuum processing chamber 22C.

In the vacuum processing chamber 22C, a bias voltage is applied to the under layer 12 to from the recording layer 13 by the sputtering process. Referring again to FIG. 4, a bias-applying power source 26 that supplies a bias voltage to the substrate holder 40 is connected to the substrate holder 40 in the vacuum processing chamber 22C for forming the recording layer 13. The bias-applying power source 26 supplies a negative bias voltage (e.g. −300 V). The bias-applying power source 26 is connected to a holder conducting section 41, which is made of an Al alloy or a Ti alloy material, of the substrate holder 40. The substrate holder 40 is fixed to the transfer mechanism 24 through a holder insulating section 42.

The substrate 11 is supported by the support springs 43. An end of each of the support springs 43 is fixed to the holder conducting section 41, and the other end is kept in contact with the end face 11a of the substrate 11. A movable electrode 45 is provided at the holder conducting section 41 at the upper side of the substrate 11. The movable electrode 45 is pushed downward by a guide plate 28 fixed to the vacuum processing chamber 22C and urged into contact with the substrate 11. The guide plate 28 is electrically insulated form the vacuum processing chamber 22C by an insulator 36.

While the bias voltage is supplied, the inside of the vacuum processing chamber 22C is set to an Ar gas atmosphere with pressure of 0.67 Pa. The recording layer 13 is formed with use of the target 32 made of, for example, a CoCrPtB material by a DC magnetron process. The thickness of the recording layer 13 is set to, for example, around 5 nm through 20 nm. In the case where the recording layer 13 is formed of a first magnetic layer (e.g. CoCr film), a non-magnetic interlayer (e.g. Ru film), and a second magnetic layer (e.g. CoCrPtB film), the layers are formed in different vacuum processing chambers. The following describes the bias application method in detail.

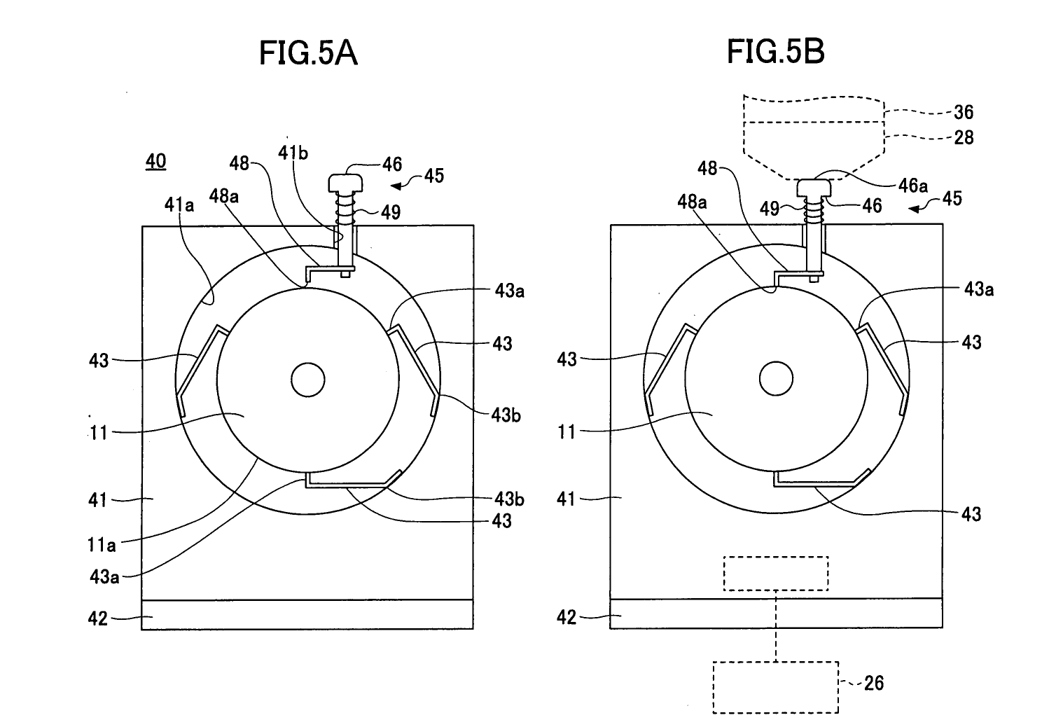

FIGS. 5A and 5B are front views of the substrate holder 40 according to a first example of the first embodiment. More specifically, FIG. 5A shows the substrate holder 40 with the movable electrode 45 being out of contact with the substrate 11, whereas FIG. 5B shows the substrate holder 40 with the movable electrode 45 being in contact with the substrate 11.

Referring to FIGS. 5A and 5B, the substrate holder 40 comprises the holder conducting section 41, the holder insulating section 42, the three support springs 43 fixed to the inner circumference of the opening 41a of the holder conducting section 41, and the movable electrode 45 provided at the upper side of the substrate 11.

Each of the support springs 43 is a spring plate made of a metal material such as Inconel (TM) and having a thickness of, for example, approximately 0.5 mm. The support spring 43 has its base section fixed to the inner circumference of the opening 41a, and a contact section 43a formed by bending a front end of the support spring 43 at approximately a right angle. The contact section 43a is in contact with the end face 11a of the outer edge of the substrate 11. The contact section 43a is configured such that a force is applied toward the center of the substrate 11 from a support point 43b of the support spring 43. The substrate 11 is thus supported on the substrate holder 40 by the three support springs 43.

Since the end face 11a of the substrate 11 is bulging outwardly as shown in FIG. 2, a front end face of the contact section 43a may be inwardly curved. It is preferable that the curve be slight in view of easier formation of a bridging section for electrically connecting the contact section 43a to the under layer 12 formed on the substrate 11.

The movable electrode 45 comprises a pole bolt 46 and a contact terminal 48 fixed to a front end of the pole bolt 46, and a spring 49 disposed between an upper portion of the pole bolt 46 and a top face of the substrate holder 40.

The pole bolt 46 is made of a metal material, which may be the same Al alloy material employed for the holder conducting section 41. The contact terminal 48 has a base section fixed to the pole bolt 46 and a contact section 48a formed by bending a front end of the contact terminal 48 at approximately a right angle. The contact terminal 48 is made of a metal material, which may be the same material as the support springs 43. A part of the contact section 48a that contacts the end face 11a of the substrate 11 may have any shape. The substrate holder 40 has a hole 41b in which the pole bolt 46 is inserted.

Alternatively, the substrate holder 40 may have a guide groove (not shown) on its surface in which the pole bolt 46 is arranged to be vertically movable. The groove may have a cover that prevents the pole bolt 46 from dropping off.

The spring 49 may be made of any elastic metal material as long as the spring 49 is formed to have a conductive surface at the least.

When the substrate holder 40 is in the vacuum processing chamber 22A for heating the substrate 11 or for forming the under layer 12, the pole bolt 46 and the contact terminal 48 are pushed upward by the spring 49 so that the contact section 48a is kept out of contact with the end face 11a of the substrate 11 as shown in FIG. 5A.

On the other hand, in the vacuum processing chamber 22C for forming the recording layer 13, a top face 46a of the pole bolt 46 of the movable electrode 45 contacts the guide plate 28 provided in the vacuum processing chamber, and the movable electrode 45 is pushed downward. Therefore, the contact section 48a comes into contact with the end face 11a on the upper side of the substrate 11 as shown in FIG. 5B. The under layer 12 on the end face 11a of the substrate 11 is electrically connected to the holder conducting section 41 of the substrate holder 40 through the movable electrode 45. Even if the movable electrode 45 is pushed downward excessively, the contact terminal 48, which is formed of a plate spring, deforms to prevent the contact terminal 48 from sliding off the end face 11a and the substrate 11 from falling off the support springs 43.

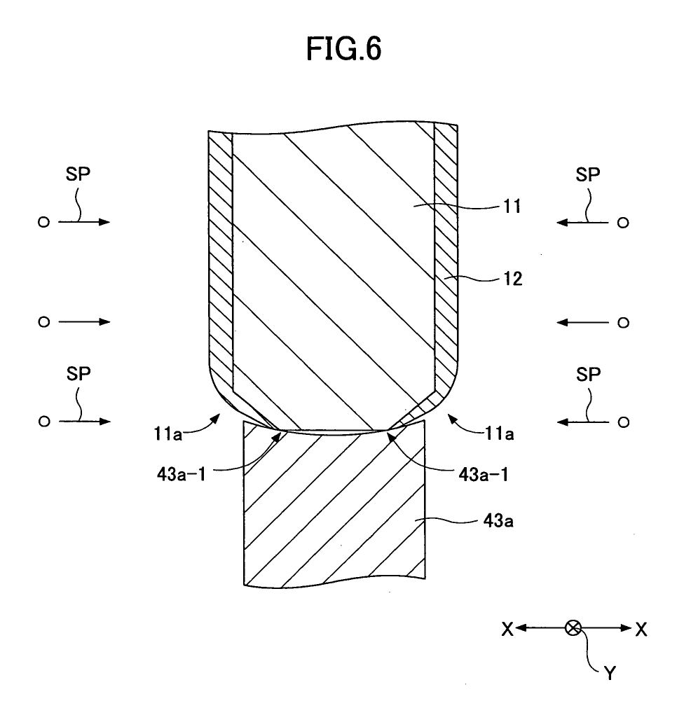

A negative bias voltage is supplied from the bias-applying power source 26 to the holder conducting section 41 of the substrate holder 40. The bias voltage is then supplied from the holder conducting section 41 to the under layer 12 of the substrate 11 through the movable electrode 45 and the three support springs 43. The movable electrode 45 has a direct contact with, and therefore electrical conduction with the under layer 12 formed on the end face 11a of the substrate 11. Each of the support springs 43 is partly in contact with the under layer 12 to be electrically connected thereto. The state of the contact is described below with reference to FIG. 6.

FIG. 6 illustrates the state of contact between the contact section 43a of the support spring 43 and the under layer 12 on the end face 11a of the substrate 11. FIG. 6 is a cross-sectional view of the substrate 11 and the contact section 43a of the support spring 43.

Referring to FIG. 6, the front end face of the contact section 43a is inwardly curved, while the end face 11a of the end face 11a of the substrate 11 is outwardly bulging. During the process of forming the under layer 12, metal particles SP are incident on the surface of substrate 11 from a direction (X direction) substantially orthogonal to the surface of the substrate 11 to form the under layer 12 on the surface and the end face 11a of the substrate 11. The under layer 12 formed around contact points 43a-1 where the contact section 43a is in contact with the end face 11a is thinner than other areas, because the metal particles SP are shielded by the contact section 43a. However, some of the metal particles SP are deposited around the contact points 43a-1, so that the under layer 12 formed on the end face 11a is bridged to the contact section 43a. The metal particles from a Y-direction are also deposited around the contact points 43a-1. As a result, the under layer 12 is electrically connected to the contact section 43a.

Referring back to FIG. 5, since the support springs 43 are in contact with the under layer 12 at three positions, the bias voltage is uniformly supplied to the under layer 12. With the movable electrode 45 and the support springs 43, the bias voltage can be surely applied to the under layer 12 even if the under layer 12 is thin.

Referring back to FIG. 3, after the recording layer 13 is formed, the substrate holder 40 is transferred to the next vacuum processing chamber 22D. When the substrate holder 40 is transferred, the movable electrode 45 is released from the guide plate 28 to permit the contact terminal 48 to be out of contact with the substrate 11.

In the vacuum processing chamber 22D, the protection film 14 such as a carbon hydride film is formed to cover the recording layer 13 by, for example, a Plasma CVD process. To form the carbon hydride film, a hydrocarbon gas, a hydrogen gas, an inert gas or the like is supplied into the vacuum processing chamber 22D, and the pressure of the vacuum processing chamber 22D is set to, for example, 5 Pa. Then, a high-frequency power (e.g. 100 W) is supplied to a plasma generating section 37 to generate plasma. Meanwhile, as in the case of forming the recording layer 13, a negative bias (e.g. −300 V) is applied to the recording layer 13 through the movable electrode 45 and the support springs 43. The carbon hydride film is thus formed on the surface of the recording layer 13.

The substrate holder 40 is then moved to the unload lock chamber 23. In the unload lock chamber 23, the magnetic disk 10 (the substrate 11) is unloaded by a robot and placed in a cartridge. The unload lock chamber 23 set to the vacuum atmosphere is set back to the atmospheric pressure, and the magnetic disk 10 is removed from the manufacturing apparatus 20.

After that, although not shown, a lubricant layer of, for example, fluorinated perfluoropolyether is formed on a surface of the protection film 14 by a dipping method. In this way, the magnetic disk 10 is produced.

According to this embodiment, when the under layer 12 is formed, the substrate 11 made of an insulating material is supported by the support springs 43 made of a conductive material. While keeping the substrate 11 supported, the movable electrode 45 is urged into contact with the end face 11a to form the recording layer 13. Since the under layer 12 is formed on the end face 11a of the substrate 11, the electric conduction between the movable electrode 45 and the under layer 12 is good. Moreover, since the under layer 12 formed on the end face 11a is bridged to a part of each of the support springs 43, the support springs 43 are electrically connected to the under layer 12. Therefore, the bias voltage is supplied to the under layer 12 through the movable electrode 45 and the support springs 43. With the bias voltage supplied in this manner, the recording layer 13 can be formed to have a coercive force uniformly distributed throughout the surface of the under layer 12 on the substrate 11. As a result, the recording density of the magnetic disk 10 can be increased. Moreover, since the bias voltage is supplied from plural points, generation of abnormal electrical discharge and defects caused by generation of abnormal electrical discharge are minimized. This contributes to improve the yield. Also, a uniform and high-quality protection film 14 can be formed by supplying a bias voltage in the same manner.

The following describes another substrate holder used for the manufacturing method according to this embodiment.

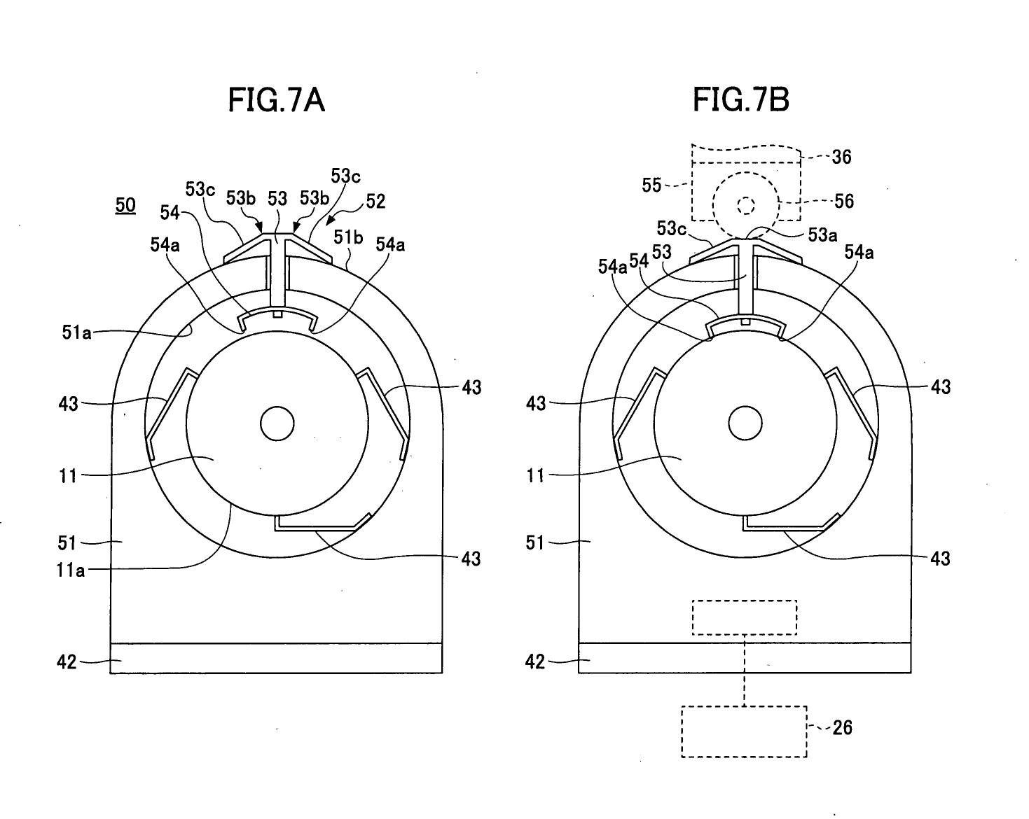

FIGS. 7A and 7B are front views of a substrate holder 50 according to a second example of the first embodiment. More specifically, FIG. 7A shows the substrate holder 50 with a movable electrode 52 being out of contact with the substrate 11, whereas FIG. 7B shows the substrate holder 50 with the movable electrode 52 being in contact with the substrate 11. Elements identical to those previously described bear the same reference numbers and are not further described.

Referring to FIGS. 7A and 7B, the substrate holder 50 comprises a holder conducting section 51, a holder insulating section 42, three support springs 43 fixed to the inner circumference of an opening 51a of the holder conducting section 51, and the movable electrode 52 provided at the upper side of the substrate 11.

The movable electrode 52 comprises a pole bolt 53, and a contact terminal 54 fixed to a front end of the pole bolt 54. Two plate spring sections 53c bent at support points 53b and extending along an upper face of the holder conducting section 51 are provided at a head of the pole bolt 53. A front end of each of the plate spring sections 53c is in contact with a top face 51b of the holder conducting section 51. The pole bolt 53 and the contact terminal 54 are pushed upward by the plate spring sections 53c so that contact sections 54a (to be discussed below) are kept out of contact with the end face 11a of the substrate 11.

The contact terminal 54 is configured to extend from the lower part of the pole bolt 53 in opposite directions along the end face 11a of the substrate 11. The contact terminal 54 includes the contact sections 54a, which are formed by bending both ends of the contact terminal 54 at approximately a right angle. A front end of each of these two contact sections 54a is arranged on a circumference of a virtual circle having substantially the same radius of the end face 11a of the substrate 11. The contact terminal 54 is made of the same material as the contact terminal 48 of the first example shown in FIG. 5.

When the substrate holder 50 is in the vacuum processing chamber for heating the substrate 11 or for forming the under layer 12, the pole bolt 53 is pushed upward by the front ends of the two plate spring sections 53c in contact with the top face 51b of the holder conducting section 51 so that the contact sections 54a are kept out of contact with the end face 11a of the substrate 11 as shown in FIG. 7A.

Referring to FIG. 7B, a bearing 56 is provided in the vacuum processing chamber for forming the recording layer 13. The bearing 56 is adapted to push the movable electrode 52 downward so that the contact sections 54a are brought into contact with the end face 11a of the substrate 11. The bearing 56 is supported by a support plate 55 on the upper side of the vacuum processing chamber through an insulator 36. The bearing 56 is configured to rotate in a moving direction of the substrate holder 50.

When the substrate holder 50 is moved to the vacuum processing chamber, the plate spring section 53c of the movable electrode 52 contacts the bearing 56. The substrate holder 50 is moved further so that a top face 53a of the pole bolt 53 reaches the bearing 56 while the plate spring sections 53c are pushed downward by the bearing 56. When the top face 53a of the pole bolt 53 reaches the bearing 56, the substrate holder 50 is stopped. The pole bolt 53 is pushed downward by the bearing 56, so that the two contact sections 54a of the contact terminal 54 come into contact with the end face 11a of the substrate 11. Even if the pole bolt 53 is pushed downward with an excessive force, the contact terminal 54 can absorb the excessive force with its elasticity. In this manner, the movable electrode 52 contacts the end face 11a on the upper side of the substrate 11.

In this state, a negative bias voltage is supplied from a bias-applying power source 26 to the substrate holder 50. The negative bias voltage is applied to the under layer 12 formed on the substrate 11 through the support springs 43 and the movable electrode 52.

As described above, the substrate holder 50 is provided with plate spring sections 53c on the upper side of the movable electrode 52. The bearing 56 rotates on the surface of the plate spring section 53c while pushing the movable electrode 52 downward. Since the bearing 56 rotates, but does not slide, on the plate spring sections 53c, particles and films thereon can be prevented from coming off. This contributes to minimizing defective magnetic disks, and consequently improves the yield.

The movable electrode 52 is provided with the contact terminal 54 having the two contact sections 54a that serve as voltage feeding points. Owing to the increase of the number of feeding points, the bias voltage can be further uniformly distributed. The upper face 51b of the holder conducting section 51 has a curved shape, although other shapes may be used alternatively.

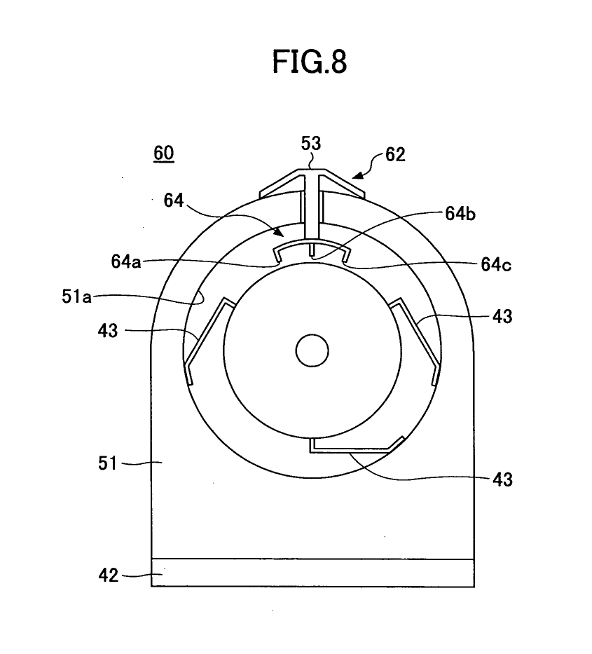

FIG. 8 is a front view of a substrate holder 60 according to a third example of the first embodiment. The substrate holder 60 of the third example is a modification of the second example. Elements identical to those previously described bear the same reference numbers and are not further described.

Referring to FIG. 8, the substrate holder 60 comprises a holder conducting section 51, a holder insulating section 42, three support springs 43 fixed to the inner circumference of an opening 51a of the holder conducting section 51, and a movable electrode 62 provided at the upper side of the substrate 11. The substrate holder 60 of the third example has the same configuration as the substrate holder 50 of the second example except a contact terminal 64 of the movable electrode 62.

The contact terminal 64 is configured to extend from the lower part of a pole bolt 53 in opposite directions along the end face 11a of the substrate 11. The contact terminal 64 includes a contact section 64a and a contact section 64c respectively on opposite ends, which are formed by bending both ends of the contact terminal 64 at approximately a right angle. The contact terminal 64 further includes a contact section 64b under the pole bolt 53. With these three contact sections 64a through 64c that simultaneously contact the end face 11a of the substrate 11, the electric conduction between the movable electrode 62 and the under layer 12 formed on the substrate 11 is further improved. The application of the bias voltage is performed in the same manner as in the substrate holder 50 of the second example, and is not further described.

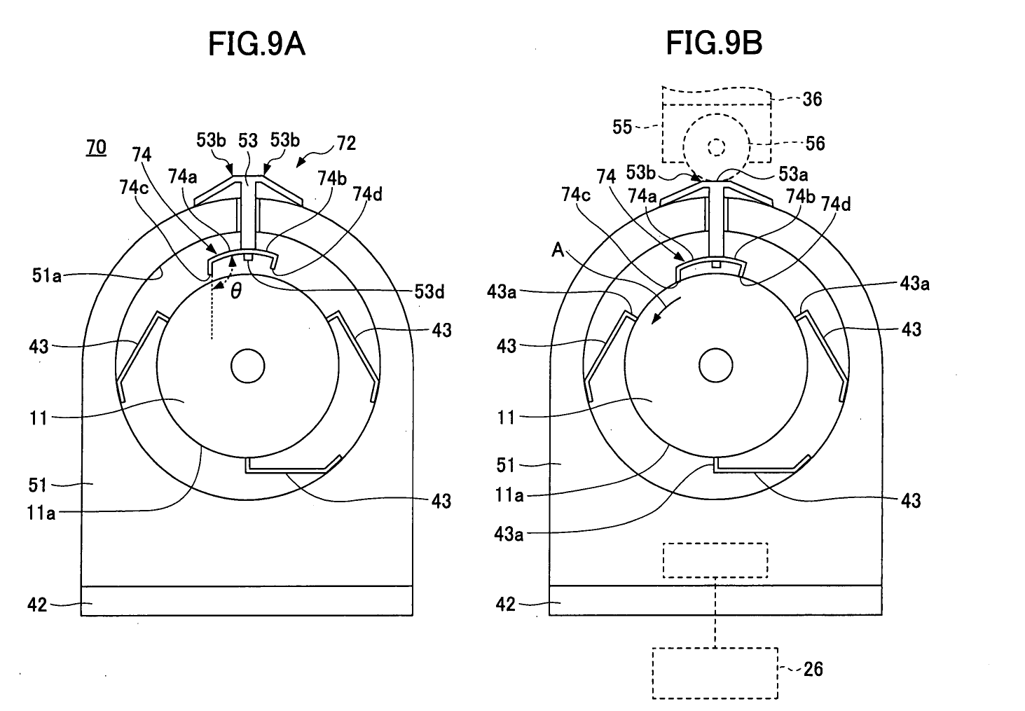

FIGS. 9A and 9B are front views of a substrate holder 70 according to a fourth example of the first embodiment. More specifically, FIG. 9A shows the substrate holder 70 with a movable electrode 72 being out of contact with the substrate 11, whereas FIG. 9B shows the substrate holder 70 with the movable electrode 72 being in contact with the substrate 11. The substrate holder 70 of the fourth example is a modification of the second example. Elements identical to those previously described bear the same reference numbers and are not further described.

Referring to FIGS. 9A and 9B, the substrate holder 70 of the fourth example comprises a holder conducting section 51, a holder insulating section 42, three support springs 43 fixed to the inner circumference of an opening 51a of the holder conducting section 51, and the movable electrode 72 provided at the upper side of the substrate 11. The substrate holder 70 has the same configuration as the substrate holder 50 of the second example except a contact terminal 74 of the movable electrode 72.

The contact terminal 74 includes arm sections 74a and 74b extending from a lower part 53d of a pole bolt 53 in opposite directions along the end face 11a of the substrate 11, and contact sections 74c and 74d respectively formed by bending front ends of the arm sections 74a and 74b at approximately a right angle. The distance between the lower part 53d of the pole bolt 53 and the contact section 74c is different from the distance between the lower part 53d and the contact section 74d. That is, the arm section 74a is longer than the arm section 74b. An angle θ between the horizontally extending part of the arm section 74a and the contact section 74c is set to the angle greater than 90 degrees. With this configuration, when the movable electrode 72 with the contact sections 74c being out of contact with the end face 11a of the substrate 11 as shown in FIG. 9A is pushed downward by the bearing 56 as shown in FIG. 9B, a rotational force in a direction indicated by an arrow A is applied to the substrate 11 by the contact section 74c. Then, the points of the end face 11a contacted by the support springs 43 are moved relative to the support springs 43 with this rotational force. The points may be moved, for example, approximately 0.1 mm through 0.2 mm. With this movement, the contact sections 43a of the support springs 43 come into contact with the end face 11a on which the under layer 12 is formed. Therefore, the electric conduction between the support springs 43 and the under layer 12 is further improved, and the bias voltage is uniformly distributed.

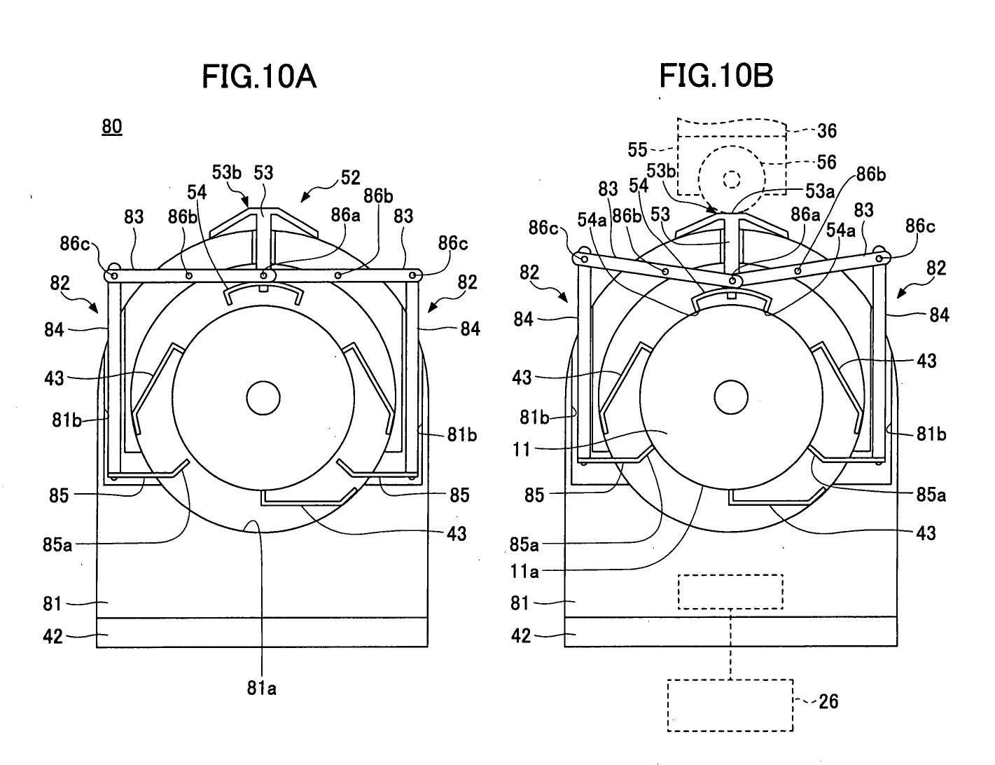

FIGS. 10A and 10B are front views of a substrate holder 80 according to a fifth example of the first embodiment. More specifically, FIG. 10A shows the substrate holder 80 with movable electrodes 52 and 82 being out of contact with the substrate 11, whereas FIG. 10B shows the substrate holder 80 with the movable electrodes 52 and 82 being in contact with the substrate 11. The substrate holder 80 of the fifth example is a modification of the second example. Elements identical to those previously described bear the same reference numbers and are not further described.

Referring to FIGS. 10A and 10B, the substrate holder 80 comprises a holder conducting section 81, a holder insulating section 42, three support springs 43 fixed to the inner circumference of an opening 81a of the holder conducting section 81, the first movable electrode 52 provided at the upper side of the substrate 11, and the two second movable electrodes 82 interlocked with the first movable electrode 52.

The first movable electrode 52, having the same configuration as the movable electrode 52 of the substrate holder 50 of the second example shown in FIG. 7, comprises a contact terminal 54 at a front end of a pole bolt 53. Each of the second movable electrodes 82 comprises first arms 83 extending horizontally from the pole bolt 53 of the first movable electrode 52 along a surface of the substrate holder 80, second arms 84 connected to the corresponding first arms 83 and extending substantially vertically, and contact terminals 85 fixed to corresponding front ends of the second arms 84.

Each of the first arms 83 has an end rotatably connected to the pole bolt 53 at a support point 86a and the other end rotatably connected to the second arm 84 at a support point 86c. There is also provided a support point 86b on the first arm 83. The support point 86b is fixed to the holder conducting section 81. A downward movement of the pole bolt 53 causes the support point 86a to move downward and the support points 86c to move upward.

The second arms 84 are arranged in guide grooves 81b provided on the holder conducting section 81. Horizontal movements of the second arms 84 are restricted by the guide grooves 81b. Vertical movements of the second arms 84 are interlocked with the vertical movements of the support points 86c moved by the first arms 83. Each of the contact terminals 85 has a contact section 85a at its front end.

When the substrate holder 80 is in the vacuum processing chamber for heating the substrate 11 or for forming the under layer 12, the pole bolt 53 is pushed upward and the contact sections 54a of the first movable electrode 52 and the contact sections 85a of the second movable electrodes 82 are kept out of contact with the end face 11a of the substrate 11 as shown in FIG. 10A. On the other hand, when the substrate holder 80 is in the vacuum processing chamber for forming the recording layer 13, the first movable electrode 52 is pushed downward by the bearing 56. Therefore, the contact sections 54a come into contact with the end face 11a as shown in FIG. 10B. At the same time, the support point 86a on the first arms 83 that are fixed at the support points 86b is moved downward, and the support points 86c are moved upward. The second arms 84 are also moved upward. With theses movements, the contact terminals 85 are moved upward, so that the contact sections 85a contact the end face 11a of the substrate 11.

In this state, a bias voltage is applied to the surface of the under layer 12 through the first movable electrode 52, the second movable electrodes 82 and the support springs 43. The bias voltage is further uniformly distributed, and therefore the coercive force of the recording layer 13 is also further uniformly distributed.

In the following, first and second working examples of the first embodiment will be described. In the first working example, the substrate holder of the first example shown in FIG. 5 is used to form a magnetic disk. In the second working example, the substrate holder of the second example shown in FIG. 7 is used to form a magnetic disk.

The substrate holder used in the first working example will now be described in detail by referring to FIG. 5. It should be noted that the uppermost position of the outer circumference of the substrate 11 in the drawing sheet is assigned to 0 degree, with the degree increasing clockwise (i.e., with the degree degreasing counterclockwise). The definition of degree is the same in the second working example.

In the substrate holder 40 used in the first working example, the support springs 43 are in contact with the end face 11a of the substrate 11 at positions of 45 degrees, 180 degrees, and 315 degrees, respectively. Further, the contact terminal 48 of the movable electrode 45 is in contact with the end face 11a of the substrate 11 at a position of 15 degrees.

The substrate holder used in the second working example will now be described in detail by referring to FIG. 7. In the substrate holder 50 used in the second working example, the positions at which the support springs 43 are in contact with the end face 11a of the substrate 11 are the same as in the substrate holder used in the first working example. The substrate holder 50 has the two contact sections 54a of the contact terminal 54 of the movable electrode 52 that are in contact with the end face 11a of the substrate 11 at positions of 15 degrees and −15 degrees, respectively.

The conditions in which magnetic disks are manufactured are identical in the first working example and the second working example, and were controlled as follows. First, a glass substrate (64 mm in diameter) having mechanical texture formed in circumferential direction was cleaned, followed by performing a substrate heating process (230° C.) in a vacuum environment by use of the manufacturing apparatus 20 shown in FIG. 3. Next, with the vacuum processing chamber set to an Argon-gas environment with a pressure of 0.5 Pa to 1.0 Pa, the DC magnetron sputter method was employed to form a seed layer (Cr-base alloy, 23 nm), an under layer (Cr-base alloy, 5 nm), a magnetic layer (CoCrPt alloy, 23 nm), and a protective film (diamond-like carbon, 4 nm) in the order named. In the process step of forming the magnetic layer, a voltage of −300 V was applied to the substrate holders of the first and second working examples, and an electrical power was set to 1000 W to form the magnetic layer, with the movable electrode being in contact with the substrate 11. With this configuration, the magnetic layer was formed in the magnetic layer forming step, with a bias voltage of −300 V being supplied to the under layer via the movable electrode and the support springs. Readjustment of the grip on the substrate was not made during the period from the forming of the seed layer to the forming of the magnetic layer.

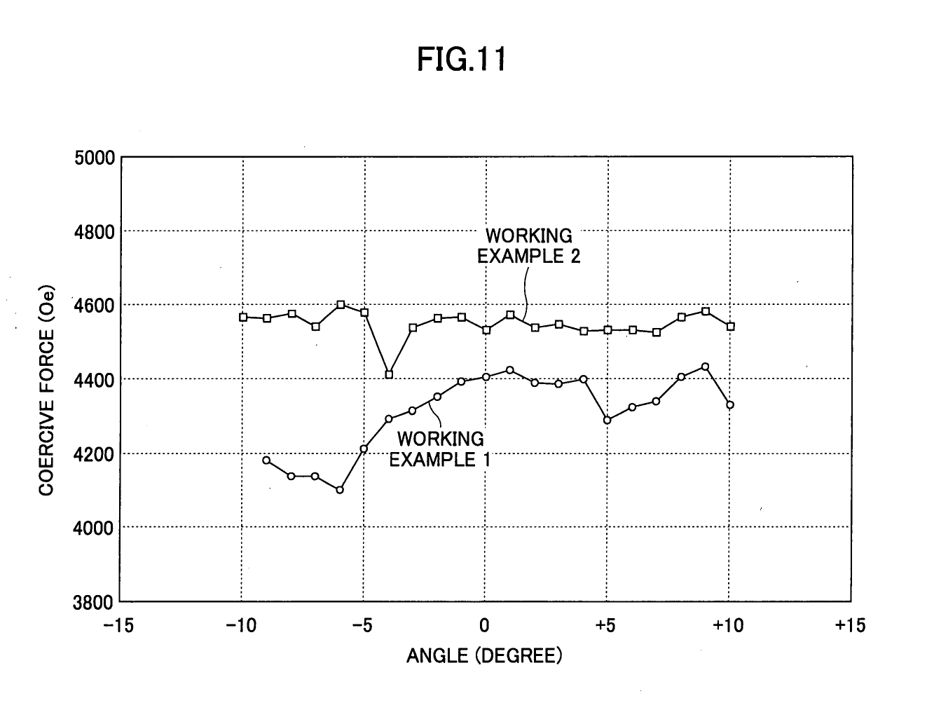

FIG. 11 is a drawing showing the characteristics of coercive force of the magnetic disk according to the working examples of the first embodiment. The vertical axis of FIG. 11 represents a coercive force measured by a Kerr-effect measurement apparatus. The horizontal axis of FIG. 11 is the angle as previously defined. Measurements were taken at one-degree intervals between −10 degrees (or −9 degrees) and 10 degrees at a radial position of 31.5 mm of the magnetic disk. The Kerr-effect measurement apparatus had a spot size of 0.4 mm.

Referring to FIG. 11, the magnetic disk of the first working example exhibited a coercive force of 4312 Oe on average over −9 degrees to 10 degrees, with a standard deviation of 101 Oe. In the first working example, the grip on the substrate was not readjusted from the forming of the seed layer to the forming of the magnetic layer. Despite this, a coercive force higher than the expected coercive force (4000 Oe) was obtained, and the standard deviation was also within the tolerable range. No anomalies such as a spark were observed.

The magnetic disk of the second working example exhibited a coercive force of 4547 Oe on average over −10 degrees to 10 degrees, with a standard deviation of 38 Oe. Excluding the data obtained for −10 degrees, the magnetic disk of the second working example exhibited a coercive force of 4546 Oe on average over −9 degrees to 10 degrees, with a standard deviation of 37 Oe. In the second working example, the grip on the substrate was not readjusted from the forming of the seed layer to the forming of the magnetic layer. Despite this, a coercive force higher than the expected coercive force (4000 Oe) was obtained, and the standard deviation was also within the tolerable range. No anomalies such as a spark were observed.

Further, the magnetic disk of the second working example exhibited an average coercive force that was 234 Oe higher than that of the magnetic disk of the first working example, which indicates the relevant substrate holder and manufacturing method are suitable to increase the recording density of magnetic disks. The magnetic disk of the second working example exhibited a coercive-force standard deviation that is as small as 37% of that of the magnetic disk of the first working example, which indicates the provision of an extremely uniform distribution of coercive forces. This is because the contact terminal 54 of the movable electrode 52 of the substrate holder 50 shown in FIG. 7 used for the second working example had two contact sections 54a. This ensures that the contact sections 54a are more reliably kept in contact with the end face 11a of the substrate 11, compared with the movable electrode 45 of the substrate holder 40 shown in FIG. 5 used for the first working example having only one contact section 48a, thereby making it possible to maintain a satisfactory electrical coupling with the under layer formed on the end face. This indicates that a plurality of contact sections provided for the contact terminal of the movable electrode is preferable over a single contact section.

According to the first working example and second working example, the substrate holder 40 and 50 shown in FIG. 5 and FIG. 7 were used, respectively, to supply a bias voltage to the under layer via the respective movable electrodes 45 and 52 and the support springs 43 in the magnetic layer forming step. This achieved an average coercive force of the magnetic disk exceeding the desired coercive force, and also achieved a substantially uniform distribution of coercive force in the circumferential direction of the magnetic disk. Further, it was learned that the number of contact sections provided on the contact terminal of the movable electrode should preferably be plural rather than one in order to attain a high coercive force and uniform coercive force distribution.

### Second Embodiment

A second embodiment of the present invention relates to a magnetic recording device equipped with a magnetic disk manufactured by the manufacturing of the first embodiment of the present invention.

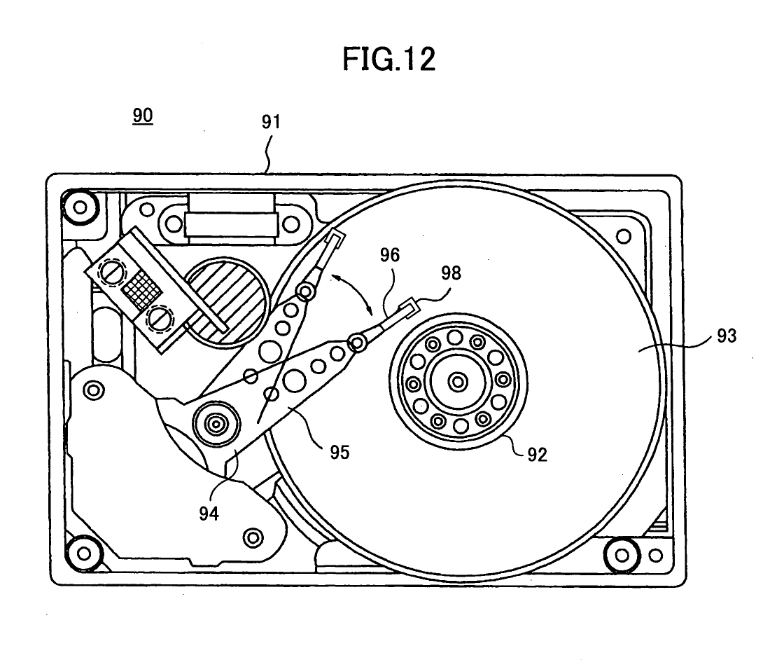

FIG. 12 shows main parts of a magnetic recording device 90 according to the second embodiment of the present invention. As shown in FIG. 11, the magnetic recording device 90 includes a housing 91, a hub 92 driven by a spindle (not shown), a magnetic disk 93 fixed to and rotated by the hub 92, an actuator unit 94, an arm 95 attached to the actuator unit 94 to be moved in a radial direction of the magnetic disk 93, a suspension 96, and a magnetic head 98 supported by the suspension 96. The components 92 through 98 are arranged in the housing 91. The magnetic head 98 is a dual head comprising a reproducing head and an inductive head of an MR element (magneto resistance effect element), a GMR element (giant magneto resistance effect element), or a TMR element (tunnel magneto resistance effect element). The basic configuration of this magnetic recording deice 90 is well known in the art and therefore not further discussed.

The magnetic disk 93 includes, for example, a magnetic disk manufactured by manufacturing method of the first embodiment. The magnetic disk 93 has a recording layer on which a coercive force is uniformly distributed throughout its surface. Therefore, the recording density of the magnetic disk 93 can be increased. Moreover, since the bias voltage is supplied from plural points, generation of abnormal electrical discharge and defects caused by the generation of the abnormal electrical discharge are minimized. This contributes to improve the yield. Therefore, a high-capacity magnetic recording device 90 can be manufactured with low manufacturing cost.

The basic configuration of the magnetic recording device 90 according to the second embodiment is not limited to the one shown in FIG. 12. The magnetic head 98 is not limited to the above-described configuration, and other magnetic heads known in the art may be employed.

While the present invention has been described in terms of preferred embodiments, it will be apparent to those skilled in the art that variations and modifications may be made without departing from the scope of the invention as set forth in the accompanying claims. For instance, the position and the number of the support springs 43 are the same throughout the first example through the fourth example. However, the position and the number of the support springs 43 may be changed as long as the advantages and effects of the present invention are not impaired.

The present application is based on Japanese Priority Applications No. 2005-002971 filed on Jan. 7, 2005, and No. 2006-002970 filed on Jan. 10, 2006, with the Japanese Patent Office, the entire contents of which are hereby incorporated by reference.

What is claimed is:

1. A magnetic disk manufacturing method, comprising:
a first step of forming a conductive layer on a surface of an insulating substrate supported by a plurality of substrate support members that are made of a conductive material and are connected to a conductive holder; and
a second step of forming a recording layer on the conductive layer by a sputtering process while applying a negative bias voltage to the conductive layer;
wherein, in the second step, a movable electrode is brought into contact with the conductive layer on an end face of the insulating substrate that is kept supported by the substrate support members, and the recording layer is formed while applying the bias voltage to the conductive layer through the movable electrode and the substrate support members.

2. The magnetic disk manufacturing method as claimed in claim 1,
wherein the substrate support members include a plurality of support springs substantially equally spaced apart from each other, each front end of the support springs being in contact with the end face of an outer edge of the insulating substrate, and
the movable electrode is urged into contact with the conductive layer on the end face between the adjacent support springs.

3. The magnetic disk manufacturing method as claimed in claim 1,
wherein the movable electrode includes an electrode body, a contact terminal provided on a front end of the electrode body, and an electrode spring,
the contact terminal is kept out of contact with the end face with a force of the electrode spring in the first step, and
the movable electrode is pressed in a direction opposite to a direction of the force of the electrode spring such that the contact terminal is kept in contact with the conductive layer on the end face in the second step.

4. The magnetic disk manufacturing method as claimed in claim 3, wherein the contact terminal includes a plurality of contact sections each of which contacts the conductive layer on the end face.

5. The magnetic disk manufacturing method as claimed in claim 3, wherein the movable electrode is arranged at the upper side of the insulating substrate, and
the movable electrode is pressed downward by a pressing part provided in a vacuum processing chamber so as to bring the contact terminal into contact with the conductive layer on the end face on the upper side of the insulating substrate.

6. The magnetic disk manufacturing method as claimed in claim 5, wherein the pressing part includes a bearing configured to rotate in a direction in which the substrate holder is moved, and
when the substrate holder is moved toward the bearing and an upper face of the movable electrode contacts the bearing, the movable electrode is pressed downward by the bearing.

7. The magnetic disk manufacturing method as claimed in claim 5, wherein the electrode spring applies a force to press the movable electrode upward so as to keep the contact terminal out of contact with the end face.

8. The magnetic disk manufacturing method as claimed in claim 2, wherein when the movable electrode contacts the end face, the movable electrode applies a force onto the insulating substrate in a circumferential direction of the insulating substrate so as to move positions of the end face contacted by the substrate support members relative to the support springs.

9. The magnetic disk manufacturing method as claimed in claim 3, wherein the contact terminal is formed of a plate spring, the contact terminal including a base section connected to the electrode body and a contact section formed by bending a front end of the contact terminal.

10. The magnetic disk manufacturing method as claimed in claim 3, wherein the electrode spring is integral with the electrode body.

11. The magnetic disk manufacturing method as claimed in claim 1, wherein, in the second step, a plurality of movable electrodes are brought into the contact with the end face of the insulating substrate at respective points substantially equally spaced.

12. The magnetic disk manufacturing method as claimed in claim 11, wherein when any one of the plural movable electrodes is pressed, all the movable electrodes are brought into contact with the end face of the insulating substrate.

13. The magnetic disk manufacturing method as claimed in claim 1, further comprising:
a third step of forming a protection film on the recording layer by a plasma CVD process while applying a negative bias voltage to the recording layer after the second step;
wherein, in the third step, the movable electrode is brought into contact with the conductive layer on the end face of the insulating substrate that is kept supported by the substrate support members, and the protection layer is formed while applying the bias voltage to the conductive layer and the recording layer through the movable electrode and the substrate support members.

14. A magnetic disk, comprising:
an insulating substrate;
a conductive layer formed on the insulating substrate; and
a recording layer formed on the conductive layer;
the magnetic disk being manufactured by a magnetic disk manufacturing method that comprises:
a first step of forming the conductive layer on a surface of the insulating substrate supported by a plurality of substrate support members that are made of a conductive material and are connected to a conductive substrate holder; and
a second step of forming the recording layer on the conductive layer by a sputtering process while applying a negative bias voltage to the conductive layer;
wherein, in the second step, a movable electrode is brought into contact with the conductive layer on an end face of the insulating substrate that is kept supported, and the recording layer is formed while applying the bias voltage to the conductive layer through the movable electrode and the substrate support members.

15. A magnetic recording device, comprising:
the magnetic disk of claim 14; and
a recording and reproducing part.

16. A substrate holding mechanism, comprising:
a conductive holder;
a plurality of conductive substrate support members each connected to the conductive holder and adapted to support an insulating substrate; and
a movable electrode that is movable to be in contact with and to be out of contact with the insulating substrate.
